(19) United States
(12) Patent Application Publication
(10) Pub. No.: US 2026/0167893 A1
(43) Pub. Date: Jun. 18, 2026

(54) FLUX CLEANER COMPOSITION AND METHODS OF FABRICATING A SEMICONDUCTOR STRUCTURE

(71) Applicant: Taiwan Semiconductor Manufacturing Company Limited, Hsinchu (TW)

(72) Inventors: Baron Huang, Hsinchu (TW); Wen-Yi Lin, New Taipei City (TW); Ming-Da Cheng, Hsinchu (TW); Zhihua Zou, Hsinchu (TW)

(21) Appl. No.: 18/978,137

(22) Filed: Dec. 12, 2024

(51) Int. Cl. C11D 1/34; C11D 3/20; C11D 3/30; C11D 3/43; H01L 21/66; H01L 23/00

(52) U.S. Cl. CPC C11D 1/345; C11D 3/2096; C11D 3/30; C11D 3/43; H10P 74/203; C11D 2111/16; H10W 72/01271; H10W 72/072; H10W 72/07211; H10W 72/07236

(57) ABSTRACT

A flux cleaner composition includes water in a range from 80% to 99%, an organic nitrogen compound in a range from 0.01% to 3%, anionic phosphate surfactant in a range from 0.01% to 3%, aprotic ketone solvent in a range from 1% to 20%, and an azo-coumarin derivative in a range from 0.01% to 5%.

### BACKGROUND

Flux is a chemical agent used to aid in the soldering process in fabricating semiconductor structures. Flux may be used to clean and prepare the surfaces of metal contacts, remove oxidation, and mitigate against oxidation during soldering. Flux may promote the formation of a strong, reliable connection between components. Such connections may be highly desirable for the performance and durability of semiconductor devices.

There are several different types of flux used in semiconductor fabrication. Rosin flux is derived from pine resin and has effective cleaning properties. Organic acid flux is made from natural acids, such as citric or lactic acid. Organic acid flux is stronger than rosin flux and is often used when more aggressive cleaning is desired. No-clean flux is designed to leave minimal or no residue, allowing for the omission of post-soldering cleaning.

After the soldering process, some residue such as polymeric flux residue, metal salt residue, etc., may remain on the semiconductor structure. The flux residue may lead to underfill delamination and cracks during a subsequent process. The metal salt residue includes compounds formed after the flux reacts with the metal, usually solder, during the deoxidation process in solder reflow.

A flux cleaner may be used to remove the flux residue remaining after the soldering process. A related flux cleaner may include a water-based solution including inorganic alkaline KOH, non-ionic polyethylene glycol surfactant, and alcohol solvent for polymeric flux residue and metal salt removal. In particular, a related flux cleaner composition may consist of 1) water of 96% 2) inorganic alkaline KOH of 0.25%, 3) nonionic polyethylene glycol surfactant of 0.75%, 4) alcohol solvent 3%. Flux cleaners that have improved flux dissolution rates that enhance flux cleaning efficiency and mitigate against metal damage are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method of making the flux cleaner composition according to one or more embodiments.

FIG. 2 is a vertical cross-sectional view of a semiconductor module according to one or more embodiments.

FIG. 3A is a vertical cross-sectional view of an intermediate structure including the first semiconductor die according to one or more embodiments.

FIG. 3B is a vertical cross-sectional view of an intermediate structure including the first semiconductor die after application of the flux material according to one or more embodiments.

FIG. 3C is a vertical cross-sectional view of an intermediate structure including the first semiconductor die on the interposer according to one or more embodiments.

FIG. 3D is a vertical cross-sectional view of an intermediate structure including the second semiconductor dies on the interposer according to one or more embodiments.

FIG. 3E is a vertical cross-sectional view of an intermediate structure after a solder reflow process according to one or more embodiments.

FIG. 3F is a vertical cross-sectional view of an intermediate structure after performing a flux cleaning process according to one or more embodiments.

FIG. 3G is a vertical cross-sectional view of an intermediate structure after performing the flux cleaning process according to one or more embodiments.

FIG. 3H is a vertical cross-sectional view of an intermediate structure after forming the BSM layer 151 according to one or more embodiments.

FIG. 4 is a flow chart illustrating a method of making a semiconductor structure (e.g., semiconductor module) according to one or more embodiments.

FIG. 5 is a vertical cross-sectional view of a package structure including the semiconductor module according to one or more embodiments.

FIG. 6A is a vertical cross-sectional view of an intermediate structure including the semiconductor module according to one or more embodiments.

FIG. 6B is a vertical cross-sectional view of an intermediate structure including the semiconductor module after application of the flux material according to one or more embodiments.

FIG. 6C is a vertical cross-sectional view of an intermediate structure including the semiconductor module on the package substrate according to one or more embodiments.

FIG. 6D is a vertical cross-sectional view of an intermediate structure after a solder reflow process according to one or more embodiments.

FIG. 6E is a vertical cross-sectional view of an intermediate structure after performing a flux cleaning process according to one or more embodiments.

FIG. 6F is a vertical cross-sectional view of an intermediate structure including the package lid according to one or more embodiments.

FIG. 6G illustrates a vertical cross-sectional view of an intermediate structure in which the BGA including the plurality of solder balls may be formed on the package substrate according to one or more embodiments.

FIG. 7 is a schematic illustration of an automated flux cleaning system according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Related flux cleaners may have several deficiencies. In particular, related flux cleaners may have a low flux dissolution rate, leading to a reduced production throughput for large package cleaning. The flux cleaners may also etch aluminum metal and, therefore, may be incompatible for use in cleaning package designs having backside metallization (BSM).

At least one embodiment of the present disclosure may include a new flux cleaner composition for flux residue (e.g., polymeric flux residue) and metal salt removal. The embodiment flux cleaner composition may address current issues for related flux cleaning efficiency enhancement especially for large dies. Embodiment flux cleaners may also lower metal (e.g., aluminum) damage so that it may be compatible with a BSM forming process.

The various embodiment flux cleaner compositions may have a low surface tension. A low surface tension may allow the various embodiment flux cleaner compositions to be used to clean residue in a small gap. The various embodiment flux cleaner compositions may also have a high flux dissolution rate resulting in a high flux cleaning efficiency. The various embodiment flux cleaner compositions may also cause little to no damage to metals, so that the various embodiment flux cleaner compositions may be compatible with a BSM process. The various embodiment flux cleaner compositions may also have a high throughput and, therefore, may be used to clean large dies.

With these characteristics, the various embodiment flux cleaner compositions may be utilized for the flux removal process following the flip chip bonding. The various embodiment flux cleaner compositions may be applicable for cleaning packaging structures of a round wafer with chips attached or square substrate bonded by sawed reconstituted wafer.

The various embodiment flux cleaner compositions may have several advantages over related flux cleaner compositions. In particular, the various embodiment flux cleaner compositions may provide an enhanced cleaning efficiency. In at least one embodiment, the embodiment flux cleaner composition may have at least twice the flux clean efficiency of the current flux cleaner composition. The embodiment flux cleaner composition may also be less likely to cause metal damage than related flux cleaner compositions. In at least one embodiment, the embodiment flux cleaner composition may reduce an aluminum metal etching rate by more than 90% in a BSM process compared to related flux cleaner compositions.

The various embodiment flux cleaner compositions may be used, for example, as part of a flux and deflux process flow for solder jointing in advanced packaging. The various embodiment flux cleaner compositions may be applied to multiple technology generations (e.g., chip-on-wafer-on-substrate, integrated fan-out, etc.) for full batch equipment (FBE) production. The various embodiment flux cleaner compositions may also be expanded to other applications for polymeric residue removal, such as tape residue removal or photoresist (PR) removal.

Some advantages of the various embodiment flux cleaner compositions have been validated through testing. In particular, a beaker flux dissolution rate test of a commercially available flux with a related flux cleaner composition and the various embodiment flux cleaner compositions at 70° C. was used to validate the flux clean efficiency of the various embodiment flux cleaner compositions. The results showed that the various embodiment flux cleaner compositions may enhance clean efficiency by about 2 times.

Further, a metal static etch rate of aluminum sheet plate was measured with a current cleaner composition and the new flux cleaner composition at 70° C., to validate metal etch damage of the new flux cleaner composition. The results showed that the new flux cleaner composition may reduce an aluminum metal etching rate (e.g., BSM etching rate) by more than 95% compared to a current flux cleaner composition.

In at least one embodiment, the embodiment flux cleaner composition (e.g., flux remover composition, flux residue remover composition, etc.) may include water, an organic nitrogen compound, anionic phosphate surfactant, an aprotic ketone solvent and an azo-coumarin derivative. In at least one embodiment, the flux cleaner composition may consist of (e.g., consist only of) or consist essentially of water, an organic nitrogen compound, anionic phosphate surfactant, an aprotic ketone solvent and an azo-coumarin derivative.

Water may be a primary component of the flux cleaner composition. The water may include, for example, deionized water, distilled water, filtered water, etc. Other suitable types of water may alternatively or additionally be used in the flux cleaner composition. The amount of water in the flux cleaner composition may range from 80% to 99%. (All percentages used herein to describe the flux cleaner composition should be construed to mean weight percent unless otherwise specified.) Greater or lesser amounts of water in the flux cleaner composition are within the contemplated scope of disclosure.

The anionic phosphate surfactant may help to reduce surface energy and improve cleaning efficiency in the flux cleaner composition. The anionic phosphate surfactant may include, for example, at least one of lauryl phosphate, sodium octyl phosphate or octylphenyl ether phosphate. Of these, octylphenyl ether phosphate has demonstrated a good balance between detergency and foaming performance. In at least one embodiment, the anionic phosphate surfactant may include a compound represented by the following chemical formula (1):

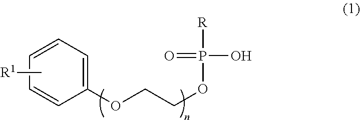

where the R1 group is C₈H₁₇, the R group is an OH group and n=10. Other suitable types of anionic phosphate surfactants may alternatively or additionally be used in the flux cleaner composition. The amount of anionic phosphate surfactant in the flux cleaner composition may be in a range from 0.01% to 3%. Greater or lesser amounts of anionic phosphate surfactant in the flux cleaner composition are within the contemplated scope of disclosure.

The aprotic ketone solvent may help to enhance the dissolution of flux residue. The aprotic ketone solvent may include, for example, 1,3-dimethyl-2-imidazolidinone, a compound represented by the following chemical formula (2):

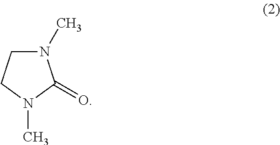

Other suitable types of aprotic solvents may be used in the flux cleaner composition in addition to aprotic ketone solvent or as an alternative to aprotic ketone solvent. Such suitable types of aprotic solvents may include, for example, diethylene glycol diethyl ether and N-methylimidazole. The amount of aprotic ketone solvent in the flux cleaner composition may be in a range from 1% to 20%. Greater or lesser amounts of aprotic ketone solvent in the flux cleaner composition are within the contemplated scope of disclosure.

The organic nitrogen compound may help to neutralize flux acid with minimum metal attack. The organic nitrogen compound may include an alkaline organic amine. In at least one embodiment, the organic nitrogen compound may include ethanolamine, a compound represented by the following chemical formula (3):

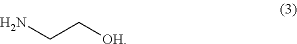

Ethanolamine has shown to provide a good balance between cleaning efficiency and metal etching performances. Other suitable types of organic nitrogen compounds may be used in the flux cleaner composition in addition to an alkaline organic amine (e.g., ethanolamine) or as an alternative to an alkaline organic amine. Such suitable types of organic nitrogen compounds may include, for example, tetramethyl ammonium hydroxide, aminopropanol (e.g., 3-amino-1-propanol), 2-(methylamino)ethanol, and 2-(2-aminoethylamino) ethanol. The amount of organic nitrogen compound in the flux cleaner composition may be in a range from 0.01% to 3%. Greater or lesser amounts of organic nitrogen compound in the flux cleaner composition are within the contemplated scope of disclosure.

The azo-coumarin derivative may help to protect a metal surface from damage. In particular, the azo-coumarin derivative may be a corrosion inhibitor that inhibits corrosion to metals. The azo-coumarin derivative may be referred to, for example, as an azo-coumarin inhibitor. In at least one embodiment, the azo-coumarin derivative may include a compound represented by the following chemical formula (4):

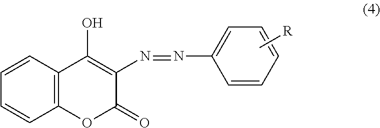

where the R group is a hydrogen atom. Other suitable azo-coumarin derivatives may be used in the flux cleaner composition in addition to the compound represented by chemical formula (4) where the R group is a hydrogen atom or as an alternative to the compound represented by chemical formula (4) where the R group is a hydrogen atom. Such suitable azo-coumarin derivatives may include, for example, the compound represented by the chemical formula (4) where the R group is a bromine atom, a chlorine atom, a methyl group, an ethoxy group, a nitrile group or a nitro group. The amount of azo-coumarin derivative in the flux cleaner composition may be in a range from 0.01% to 5%. Greater or lesser amounts of azo-coumarin derivative in the flux cleaner composition are within the contemplated scope of disclosure.

In at least one embodiment, the amount of water in the flux cleaner composition may be less than 96%. In at least one embodiment, the amount of organic nitrogen compound may be greater than the amount of anionic phosphate surfactant. In at least one embodiment, the amount of organic nitrogen compound may be greater than the amount of azo-coumarin derivative. In at least one embodiment, the amount of aprotic ketone solvent in the flux cleaner composition may be greater than the amount of organic nitrogen compound. In at least one embodiment, the amount of aprotic ketone solvent in the flux cleaner composition may be at least 3 times the amount of organic nitrogen compound. In at least one embodiment, the amount of aprotic ketone solvent in the flux cleaner composition may be substantially the same as the amount of azo-coumarin derivative.

In at least one embodiment, the flux cleaner composition may include, consist of or consist essentially of water in a range from 80% to 99%, alkaline organic amine (e.g., organic nitrogen compound) in a range from 0.01% to 3%, anionic phosphate surfactant in a range from 0.01% to 3%, aprotic ketone solvent in a range from 1% to 20%, and azo-coumarin inhibitor (e.g., azo-coumarin derivative) in a range from 0.01% to 5%. In at least one embodiment, the flux cleaner composition may include about 95% water, about 1% alkaline organic amine, about 0.1% anionic phosphate surfactant, about 3.8% aprotic ketone solvent, and about 0.1% azo-coumarin inhibitor.

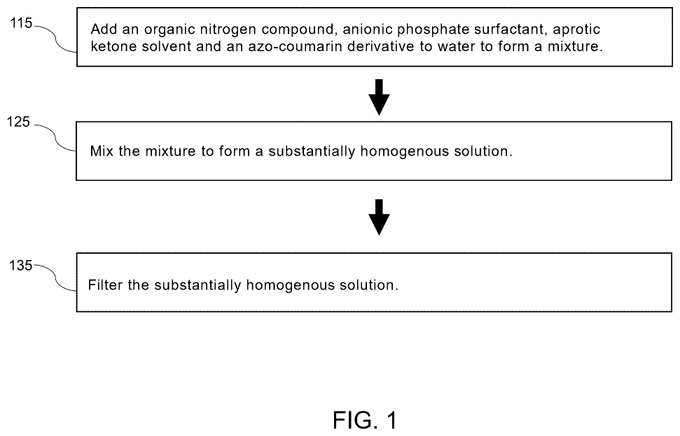

FIG. 1 is a flow chart illustrating an embodiment method of making the flux cleaner composition according to one or more embodiments. Step 115 of the embodiment method may include adding an organic nitrogen compound, anionic phosphate surfactant, aprotic ketone solvent and an azo-coumarin derivative to water (e.g., deionized water) to form a mixture. Each of the organic nitrogen compound, anionic phosphate surfactant, aprotic ketone solvent, azo-coumarin derivative and water may be weighed to ensure that the ingredients have the proper weight percentages in the final mixture.

Step 125 may include mixing the mixture to form a substantially homogenous solution. The mixture may be mixed by hand with a hand-held mixing tool or by using an electrical mixer. The electrical mixer may include, for example, a stir wheel mixer, a propeller mixer, high-shear mixer, static mixer, magnetic stirrer, paddle mixer or ultrasonic homogenizer. The mixture may be mixed until the mixture has become a substantially homogenous solution. In at least one embodiment method, the mixture may be mixed for a duration in a range from 5 minutes to 30 minutes.

In at least one embodiment method, the mixture may be heated (e.g., during mixing) to ensure the ingredients are properly dissolved. In at least one embodiment, the mixture may be heated to a temperature in a range from 40° C. to 60° C.

Step 135 may include filtering the solution (e.g., the substantially homogenous solution). The solution may be filtered to remove any solid particles in the solution. The solution may be filtered, for example, by pouring the solution through a 0.2 micron (e.g., 0.2 pm filter). In at least one embodiment, the solution may be poured through the 0.2 micron filter into a clean container such as a clean plastic bottle. In at least one embodiment, the solution may be poured two or more times through the 0.2 micron filter. The solution may alternatively or additionally be filtered by pouring the solution through a 0.1 micron filter. The solution may alternatively or additionally be filtered by pouring the solution through a depth filter, ultrafiltration membrane, cross-flow filter, sterile filter, etc.

In at least one embodiment, the flux cleaner composition may be prepared by adding about 1 gram of an organic amine alkaline, about 0.1 gram of an anionic phosphate surfactant, about 3.8 grams of an aprotic ketone solvent, and about 0.1 gram of an azo-coumarin inhibitor in about 95 grams of deionized water to form a mixture. The mixture may then be mixed on a stir wheel until the mixture is a substantially homogeneous solution. The solution may then be filtered with a 0.2 micron filter into a plastic bottle.

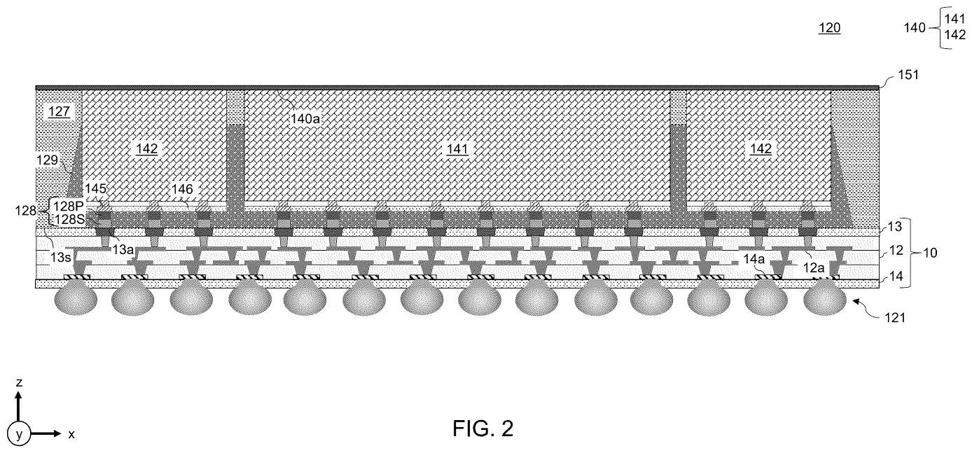

FIG. 2 is a vertical cross-sectional view of a semiconductor module 120 according to one or more embodiments. The semiconductor module 120 may be fabricated by a method in which the embodiment flux cleaner composition may be utilized.

The semiconductor module 120 may include one or more semiconductor dies 140 (e.g., first structures) on an interposer 10 (e.g., second structure). The semiconductor module 120 may also include one or more interconnects 128. The interconnects 128 may electrically couple the semiconductor dies 140 to the interposer 10. The semiconductor module 120 is not limited to any particular configuration. The semiconductor module 120 may include, for example, a flip chip-chip scale package (FC-CSP) design, a chip-on-wafer-on-substrate design, an integrated fan-out design, and so on.

The interposer 10 is not necessarily limited to any particular materials or configuration. The interposer 10 may include, for example, organic material (e.g., dielectric polymer), inorganic material (e.g., silicon), glass substrate, etc. In at least one embodiment, the interposer 10 may include a plurality of dielectric material layers 12 and a plurality of redistribution layers 12a stacked alternately. The number of the dielectric material layers 12 and/or the number of redistribution layers 12a in the interposer 10 are not limited by the disclosure.

In at least one embodiment, the dielectric material layers 12 may include, for example, polyimide (PI), epoxy resin, acrylic resin, phenol resin, benzocyclobutene (BCB), polybenzoxazole (PBO), or any other suitable polymer-based dielectric material. In some embodiments, the redistribution layers 12a may include conductive materials. The conductive materials may include metals, metal alloys, and/or other metal-containing compounds (e.g., Cu, Al, Mo, Co, Ru, W, Ti, TiN, Ta, TaN, WN, etc.). Other suitable metal materials are within the contemplated scope of disclosure.

The redistribution layers 12a may include metallic connection structures, i.e., metallic structures that provide electrical connection between nodes in the structure. In at least one embodiment, the redistribution layers 12a may include a plurality of metal traces (lines) and a plurality of metal vias connecting the plurality metal traces to each other. The metal traces may be respectively located on the dielectric material layers 12 and may extend in the x-direction (first horizontal direction) and y-direction (second horizontal direction) on an upper surface of the dielectric material layers 12. The thickness of the metal traces of the redistribution layers 12a may be in a range from 2 microns to 40 microns, such as from 4 microns to 10 microns, although lesser or greater thicknesses may also be used.

The interposer 10 may also include an upper passivation layer 13 on the chip-side surface of the interposer 10. The upper passivation layer 13 may include, for example, silicon oxide, silicon nitride, low-k dielectric materials such as carbon-doped oxides, extremely low-k dielectric materials such as porous carbon doped silicon dioxide, a combination thereof or other suitable material. Interposer upper bonding pads 13a may be formed in the upper passivation layer 13. The interposer upper bonding pads 13a may be formed of conductive materials such as metals, metal alloys, and/or other metal-containing compounds (e.g., Cu, Al, Mo, Co, Ru, W, Ti, TiN, Ta, TaN, WN, etc.). Other suitable metal materials are within the contemplated scope of disclosure.

The interposer 10 may also include a lower passivation layer 14 on the board-side surface of the interposer 10. The lower passivation layer 14 may be formed of the same materials as the upper passivation layer 13. The lower passivation layer 14 may be formed of the same material as the upper passivation layer 13. The interposer 10 may also include interposer lower bonding pads 14a in the lowermost dielectric material layer 12 or alternatively in the lower passivation layer 14. The interposer lower bonding pads 14a may be bonded to and electrically connected to the redistribution layers 12a. The interposer lower bonding pads 14a may be formed of the same material as the interposer upper bonding pads 13a.

The semiconductor module 120 may also include a plurality of C4 bumps 121 on the board-side surface of the interposer 10. The C4 bumps 121 may be formed on the interposer lower bonding pads 14a on the board-side surface of the interposer 10, respectively. The C4 bumps 121 may include underbump metallurgy (UBM) layers (not shown) on the interposer lower bonding pads 14a. The C4 bumps 121 may further include a contact pad (e.g., copper/nickel contact pad) (not shown) on the UBM layers and a solder bump (e.g., SnAg solder bump) on the contact pad.

The semiconductor dies 140 may be attached to the chip-side of the interposer 10. The semiconductor dies 140 may include one or more first semiconductor dies 141 and one or more second semiconductor dies 142. The semiconductor module 120 may include any number, size and arrangement of the semiconductor dies 140. Generally, a thickness in the z-direction of each of the semiconductor dies 140 may be substantially the same. Thus, the upper surfaces of each of the first semiconductor die 141 and second semiconductor die 142 may be substantially coplanar (e.g., formed in the same x-y plane), and referred to collectively as the semiconductor die upper surface 140a.

Each of the semiconductor dies 140 may include, for example, a singular semiconductor die structure, a system on chip die, or a system on integrated chips die, and may be implemented by chip-on-wafer-on-substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., SOC die), and the second semiconductor dies 142 may include an ancillary die (e.g., memory/SOC die, HBM die, etc.).

Each of the semiconductor dies 140 may include a die passivation layer 146 on a side of the semiconductor dies 140 facing the interposer 10. The die passivation layer 146 may be formed of the same material as the upper passivation layer 13 of the interposer 10. Each of the semiconductor dies 140 may also include die bonding pads 145 in the die passivation layer 146. The die bonding pads 145 may be formed of the same material as the interposer upper bonding pads 13a and the interposer lower bonding pads 14a.

The interconnects 128 may connect the die bonding pads 145 of the semiconductor dies 140 to the interposer upper bonding pads 13a of the interposer 10. The interconnects 128 may include, for example, microbumps. The interconnects 128 may include, for example, metal pillars 128P on the die bonding pads 145. The metal pillars 128P may be formed of copper, nickel or other suitable metals. The interconnects 128 may also include solder joints 128S connecting the metal pillars 128P to the interposer upper bonding pads 13a. The solder joints 128S may be formed, for example, of a solder material such as SnAg or other suitable solder material.

The semiconductor module 120 may also include an underfill layer 129 may be formed on the interposer 10 and under and around the semiconductor dies 140. The underfill layer 129 may also be formed around the interconnects 128. The underfill layer 129 may thereby securely fix the semiconductor dies 140 to the interposer 10. The underfill layer 129 may be formed of an epoxy-based polymeric material or other suitable material.

The semiconductor module 120 may also include an upper molding layer 127 formed around the semiconductor dies 140. The upper molding layer 127 may have an outer sidewall that is substantially aligned with the outer sidewall of the interposer 10. The upper molding layer 127 may also have an upper surface that is substantially uniform (e.g., flat) and substantially coplanar with the upper surface 140a of the semiconductor dies 140. The upper molding layer 127 may also be formed in a die-to-die gap between the semiconductor dies 140 and bonded to the inner sidewalls of the semiconductor dies 140. The upper molding layer 127 may also be bonded to the upper surface 13s of the upper passivation layer 13. The upper molding layer 127 may include a polymeric material and in particular, an epoxy-based polymeric material. Other suitable molding materials may be used.

The semiconductor module 120 may also include a backside metal (BSM) layer 151 on the upper surface of the molding material layer 127 and on the upper surface 140a of the semiconductor dies 140. The BSM layer 151 may be thermally conductive and improve a thermal dissipation characteristic of the semiconductor module 120. An outer edge of the BSM layer 151 may be substantially aligned with an outer sidewall of the molding material layer 127. The BSM layer 151 may cover an entire upper surface of the semiconductor module 120, including an entirety of the upper surface of the molding material layer 127 and/or an entirety of the upper surface 140a of the semiconductor dies 140. The BSM layer 151 may have a thickness in a range from 1 μm to 10 μm. Other suitable thicknesses may be used for the BSM layer 151. The BSM layer 151 may have a substantially uniform thickness. The BSM layer 151 may include a thermally conductive metal such as aluminum, copper or a copper alloy. Other conductive metals such as titanium, nickel, gold and silver may be included in the BSM layer 151.

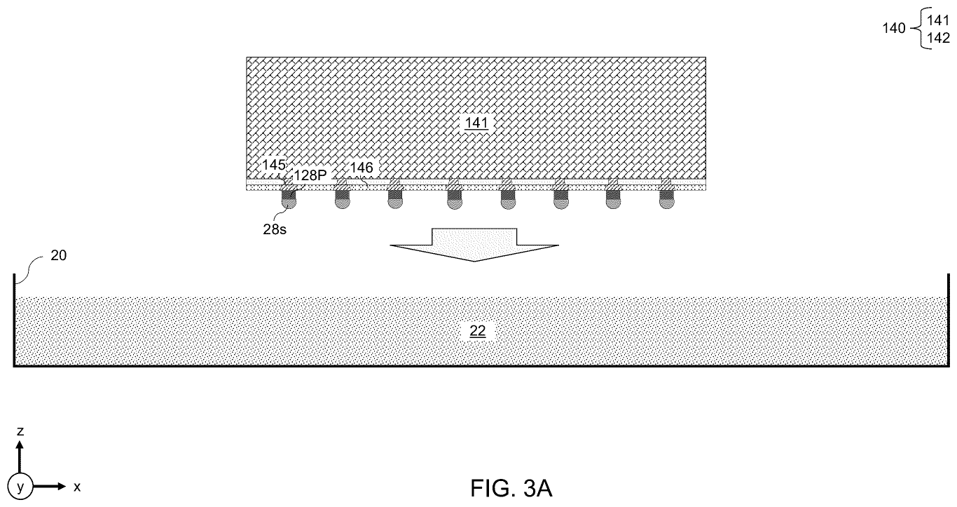

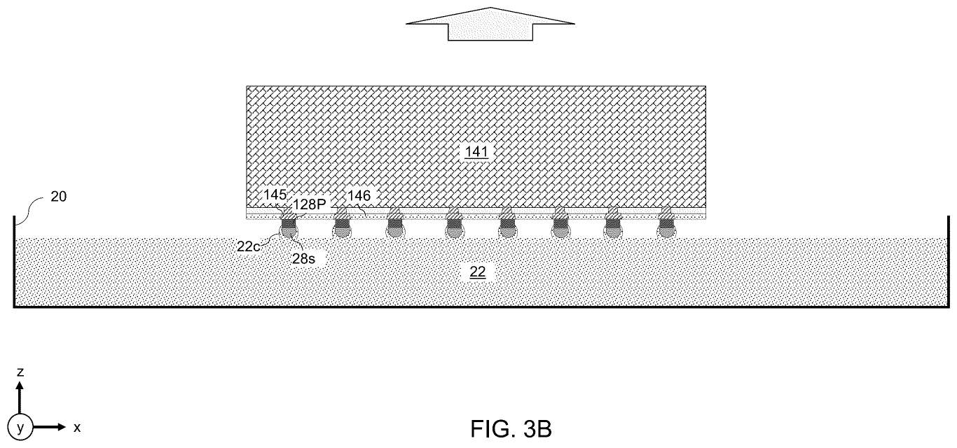

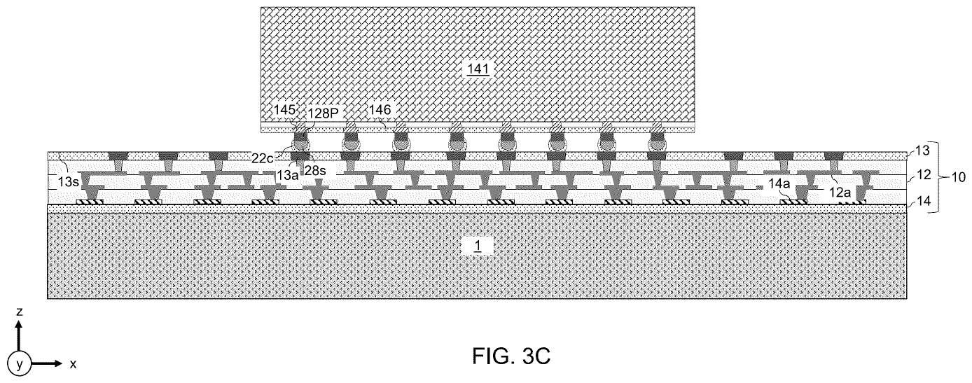

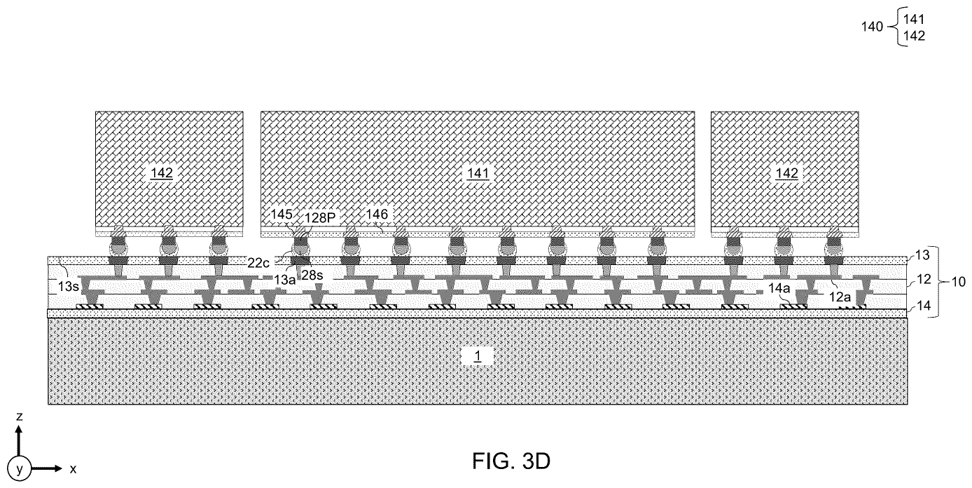

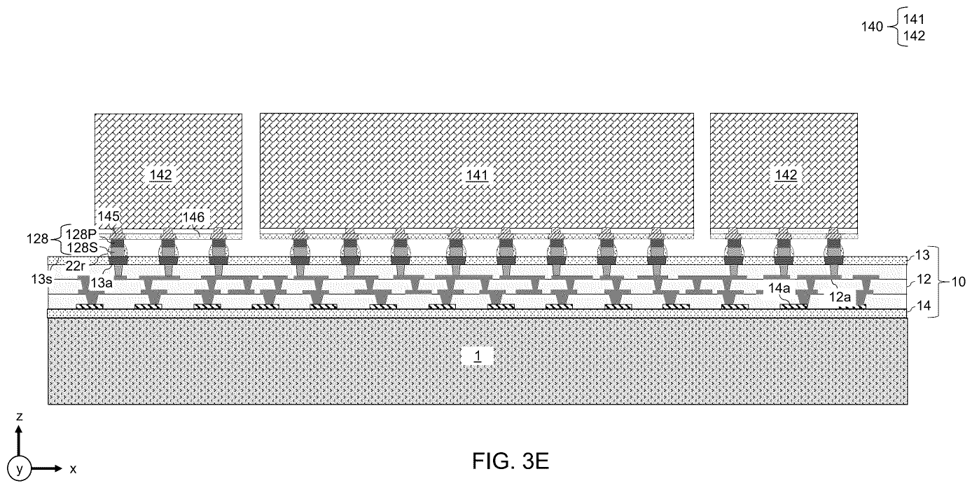

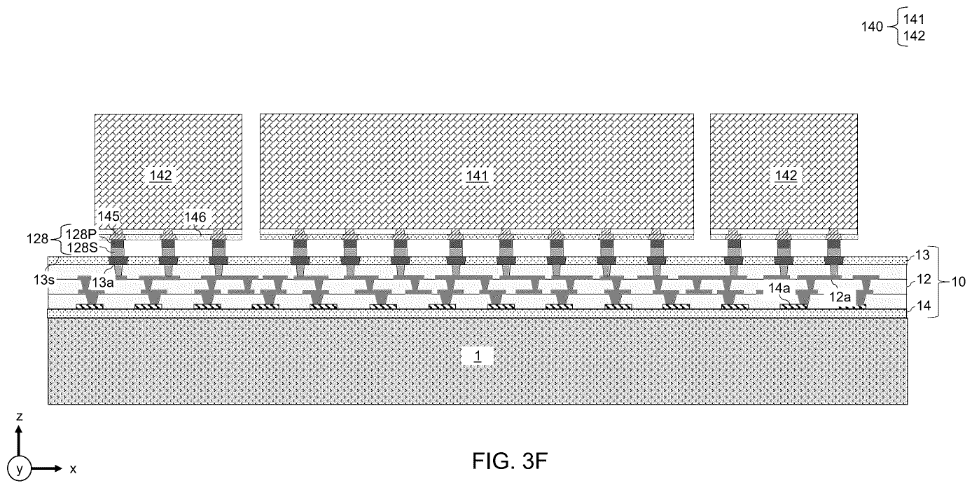

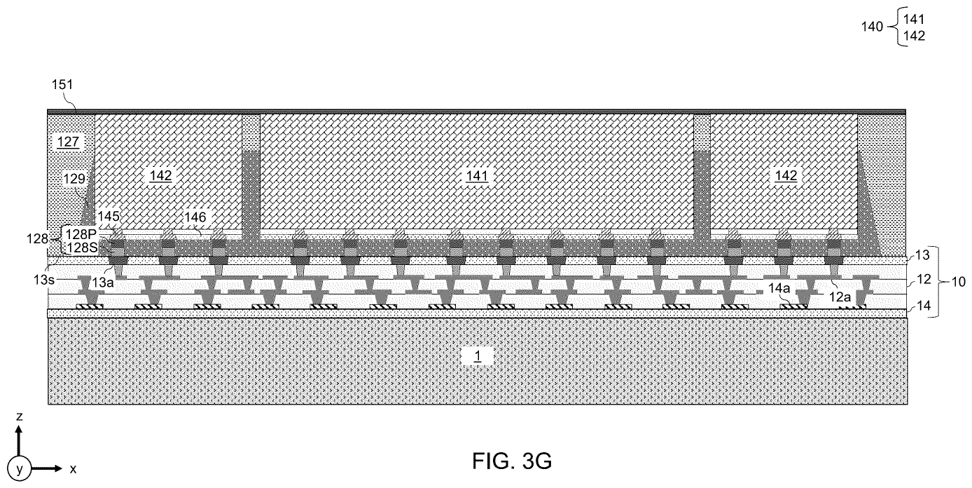

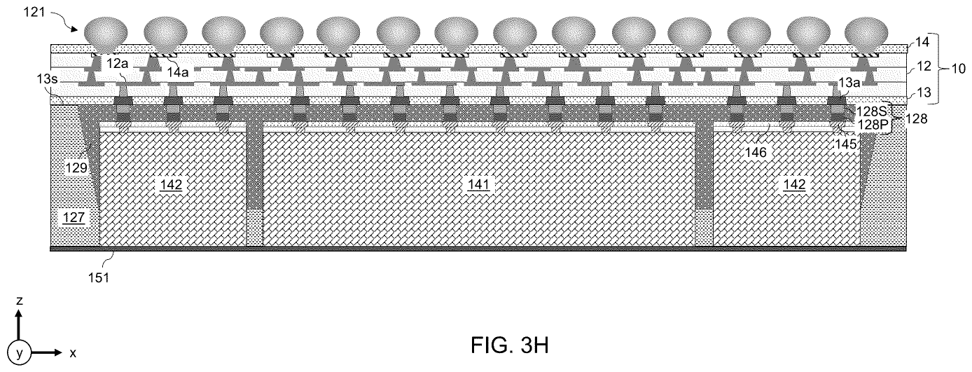

FIGS. 3A-3H illustrate various intermediate structures in a method of forming the semiconductor module 120 according to one or more embodiments. FIG. 3A is a vertical cross-sectional view of an intermediate structure including the first semiconductor die 141 according to one or more embodiments. Prior to mounting the semiconductor dies 140 on the interposer 10, a flux material 22 may be applied to the solder balls 28s on the semiconductor dies 140. The solder balls 28s may be transformed into the solder joints 128S in a subsequent reflow process.

As illustrated in FIG. 3A, a process of applying the flux material 22 to the solder balls 28s may begin by positioning the first semiconductor die 141 over a volume of the flux material 22. The first semiconductor die 141 may be positioned over the flux material 22 by an electromechanical pick-and-place (PNP) machine.

The flux material 22 may be applied to the solder balls 28s by a flux dipping process. The flux material 22 may include, for example, a polymeric flux (e.g., a flux such as rosin flux, epoxy flux and polyethylene glycol (water soluble) which use organic polymers as a vehicle). The flux material 22 may also include an organic acid flux or inorganic acid flux. Other suitable flux materials are within the contemplated scope of this disclosure. The flux material 22 may be contained in a container 20. The flux material 22 may include, for example, a polymeric flux material. A depth of the flux material 22 in the container 20 may be maintained at a level sufficient to allow the solder balls 28s to be immersed in the flux material 22. The PNP machine may lower the first semiconductor die 141 into the flux material 22 so that the solder balls 28s may be dipped in (e.g., immersed in) the flux material 22.

FIG. 3B is a vertical cross-sectional view of an intermediate structure including the first semiconductor die 141 after application of the flux material 22 according to one or more embodiments. As illustrated in FIG. 3B, after the flux dipping process in which the solder balls 28s may be dipped in the flux material 22, the electromechanical PNP machine may raise the solder balls 28s out of the flux material 22. A portion of the flux material 22 may adhere to the solder balls 28s and form a flux material coating 22c on a surface of the solder balls 28s. In at least one embodiment, a thickness of the flux material coating 22c may be at least 5% of the diameter of the solder balls 28s. A portion of the flux material 22 may also adhere to a lower portion of the metal pillar 128P on which the solder balls 28s are located. In at least one embodiment, the flux material 22 may adhere to the lowest 10% to 50% of the metal pillar 128P.

FIG. 3C is a vertical cross-sectional view of an intermediate structure including the first semiconductor die 141 on the interposer 10 according to one or more embodiments. As illustrated in FIG. 3C, the interposer 10 may be supported by a carrier substrate 1. The carrier substrate 1 may include a semiconductor substrate, an insulating substrate, or a conductive substrate. In one embodiment, the carrier substrate 1 may include an optically transparent material such as glass or sapphire. The interposer 10 may be adhered to the carrier substrate 1 by an adhesive layer (not shown) on an upper surface of the carrier substrate 1. In this embodiment, the adhesive layer may include a light-to-heat conversion (LTHC) layer or thermally decomposing adhesive material.

The electromechanical PNP machine may position the first semiconductor die 141 over the interposer 10 such that the solder balls 28s coated with the flux material coating 22c are over the interposer upper bonding pads 13a. The electromechanical PNP machine may then lower the first semiconductor die 141 down onto the interposer 10 such that the solder balls 28s coated with the flux material coating 22c are on the interposer upper bonding pads 13a.

FIG. 3D is a vertical cross-sectional view of an intermediate structure including the second semiconductor dies 142 on the interposer 10 according to one or more embodiments. As illustrated in FIG. 3D, after the first semiconductor die 141 is placed on (e.g., attached to) the interposer 10, the second semiconductor dies 142 may be placed on (e.g., attached to) the interposer 10 by the electromechanical PNP machine. Before being placed on the interposer 10, the flux material 22 may be applied to the second semiconductor die 142 using the same process used for the first semiconductor die 141 (see FIGS. 3A-3B). In particular, the electromechanical PNP machine may lower the second semiconductor dies 142 down into flux material 22 and lift the second semiconductor dies 142 out of the flux material 22, so that a flux material coating 22c is formed on a surface of the solder balls 28s.

It should be noted that the order in which the semiconductor dies 140 are placed on the interposer 10 is not necessarily important. In at least one embodiment, the second semiconductor dies 142 may be placed on the interposer 10 prior to placing the first semiconductor dies 141 on the interposer 10. In at least one embodiment, the first semiconductor dies 141 and second semiconductor dies 142 may be placed concurrently on the interposer 10.

It should also be noted that the flux material 22 may be applied to the solder balls 28s by means other than dipping the solder balls 28s in the flux material 22. In at least one embodiment, the flux material 22 may be sprayed onto the C4 bumps 121 by a sprayer device (e.g., using selective flux jetting system). In at least one embodiment, the flux material 22 may be sprayed onto the C4 bumps 121 after the semiconductor dies 140 have been placed on the interposer 10. In at least one embodiment, the flux material 22 may also be sprayed onto the interposer upper bonding pads 13a prior to placing the semiconductor dies 140 on the interposer 10. In that case, the interposer upper bonding pads 13a may also include a flux material coating 22c similar to the flux material coating 22c on the solder balls 28s.

FIG. 3E is a vertical cross-sectional view of an intermediate structure after a solder reflow process according to one or more embodiments. As illustrated in FIG. 3E, after the semiconductor dies 140 are placed on the interposer 10, a reflow process may be performed. The reflow process may transform the solder balls 28s into the solder joint 128S.

The reflow process may be performed by placing the intermediate structure in a reflow oven. In at least one embodiment, the reflow oven may include a nitrogen atmosphere to prevent oxidation of the solder material of the solder ball 28s. The reflow oven may include a controlled heating profile including a preheat phase where the temperature is gradually increased, a soak phase having a substantially constant temperature so that the intermediate structure reaches a uniform temperature, and a reflow phase in which the temperature of the reflow oven is increased to a high temperature above the melting point of the solder material. The high temperature may cause the solder balls 28s to liquefy and flow so that a space between the metal pillar 128P and the interposer upper bonding pad 13a may be substantially filled with solder material from the solder ball 28s. The temperature of the reflow oven may then be gradually lowered to cause a controlled cooling of the reflowed solder material. The cooled solder material may solidify to form the solder joint 128S.

In at least one embodiment, the heating stages of the reflow process may be designed not only to melt the solder material but also to activate the flux material coating 22c. The activated flux material coating 22c may enhance the removal of oxides and impurities on the surfaces of the solder balls 28s and interposer upper bonding pads 13a. As the flux material coating 22c is heated by the reflow process, its solvent components and some active ingredients may evaporate or decompose, producing gases that escape from the reflow oven.

However, not all of the flux material coating 22c may be consumed during the reflow process. After the reflow process, a portion of the flux material coating 22c may remain as flux residue 22r on and around the solder joint 128S. In particular, the flux residue 22r may remain on a portion of the metal pillar 128P and on the interposer upper bonding pad 13a. In at least one embodiment, the flux residue 22r may include polymeric flux residue.

FIG. 3F is a vertical cross-sectional view of an intermediate structure after performing a flux cleaning process according to one or more embodiments. The remaining flux residue 22r, in instance in which the flux residue 22r may be left on the intermediate structure, may lead to issues such as corrosion, poor electrical performance, or even physical damage over time. Therefore, after the reflow process is used to form the solder joint 128S, a flux cleaning process may be performed to remove any flux residue 22r on or around the solder joint 128S, the metal pillar 128P and the interposer upper bonding pad 13a.

The flux cleaning process may include a pre-rinse step in which the intermediate structure (e.g., the solder joint 128S, metal pillar 128P and interposer upper bonding pad 13a) may be immersed in or sprayed with deionized water or a mild cleaning solution to begin breaking down the flux residue 22r before the main cleaning cycle. This step may help soften and remove a loosely adhered portion of the flux residue 22r.

A cleaning step may then be performed using the flux cleaner composition according to one more embodiments (e.g., prepared by a method illustrated by the flowchart in FIG. 1). In the cleaning step, the intermediate structure may be immersed in an embodiment flux cleaner composition. In at least one embodiment, an entirety of the intermediate structure including the carrier substrate 1 (e.g., semiconductor wafer) may be immersed in an embodiment flux cleaner composition. In at least one embodiment, at least the solder joint 128S, metal pillar 128P and interposer upper bonding pad 13a of the intermediate structure may be immersed in an embodiment flux cleaner composition. The intermediate structure may alternatively or additionally be sprayed with an embodiment flux cleaner composition using a sprayer device. In at least one embodiment, at least the solder joint 128S, metal pillar 128P and interposer upper bonding pad 13a of the intermediate structure may be sprayed with the embodiment flux cleaner composition.

The embodiment flux cleaner composition may dissolve the flux residue 22r remaining on and around the solder joint 128S, metal pillar 128P and interposer upper bonding pad 13a. In particular, the aprotic ketone solvent may help to enhance the dissolution of flux residue 22r. The anionic phosphate surfactant may help to reduce surface energy and improve cleaning efficiency of the flux cleaner composition. The organic nitrogen compound (e.g., alkaline organic amine) may work to neutralize flux acid with minimal damage to exposed metal surfaces in the intermediate structure. The azo-coumarin derivative (e.g., azo-coumarin inhibitor) may protect the exposed metal surfaces in the intermediate structure from damage (e.g., etching, corrosion, etc.) caused by the flux cleaner composition.

In at least one embodiment, the cleaning step may include agitation to enhance the cleaning action of the embodiment flux cleaner composition. The agitation may include, for example, ultrasonic agitation, rotational agitation, and high-pressure spray jets or nozzles that direct the flux cleaner composition at the intermediate structure (e.g., on and around the solder joint 128S, metal pillar 128P and interposer upper bonding pad 13a) from one or more angles.

After the cleaning step, the intermediate structure (e.g., on and around the solder joint 128S, metal pillar 128P and interposer upper bonding pad 13a) may be rinsed with water (e.g., deionized water) to removes any remaining cleaning solution, along with any flux residue 22r. The intermediate structure may then be dried using a hot air blower (e.g., directing heated air onto the intermediate structure), vacuum drying (e.g., using reduced pressure to evaporate residual moisture quickly, or infrared heating. The intermediate structure may then be inspected using optical or X-ray inspection to verify that all of the flux residue 22r has been removed and to ensure that the solder joint 128S is high-quality and reliable.

FIG. 3G is a vertical cross-sectional view of an intermediate structure after performing the flux cleaning process according to one or more embodiments. As illustrated in FIG. 3G, after the flux cleaning process, the underfill layer 129 may be deposited on (e.g., injected onto) the upper surface 13s of the upper passivation layer 13. The underfill layer 129 may be formed under and around the semiconductor dies 140 and around the interconnects 128. The underfill layer 129 may then be cured, for example, in a box oven.

The molding material layer 127 may then be deposited on the upper surface 13s of the upper passivation layer 13 and on and around the semiconductor dies 140. The molding material layer 127 may be formed by dispensing a liquid molding material (e.g., epoxy molding material) onto the intermediate structure of FIG. 3F by a suitable dispensing tool. The molding material layer 127 may then be cured. After the molding material layer 127 has been adequately cured, the molding material layer 127 may be planarized so as to make the upper surface of the molding material layer 127 to be substantially coplanar with the upper surface of the first semiconductor die 141 and second semiconductor dies 142. The molding material layer 127 may be planarized, for example, by grinding, chemical mechanical polishing (CMP) or other suitable planarization technique.

After the molding material layer 127 has been planarized, the BSM layer 151 may be formed on the backside of the intermediate structure. The BSM layer 151 may be formed, for example, by an electrochemical plating process (also known as ECP or an electroplating process). Other methods of forming the BSM layer 151 (e.g., deposition, lamination, etc.) on the semiconductor module 120 are within the contemplated scope of disclosure.

FIG. 3H is a vertical cross-sectional view of an intermediate structure after forming the BSM layer 151 according to one or more embodiments. As illustrated in FIG. 3H, after forming the BSM layer 151, the carrier substrate 1 may be detached from the interposer 10. The carrier substrate 1 may be detached from the interposer 10, for example, by deactivating the adhesive layer (not shown) adhering the carrier substrate 1 to the interposer 10. The adhesive layer may be deactivated, for example, by a thermal anneal at an elevated temperature (e.g., for a thermally-deactivated adhesive material, or by exposing the adhesive layer to ultraviolet light (e.g., for an ultraviolet-deactivated adhesive material).

The intermediate structure may then be inverted so that the lower passivation layer 14 of the interposer 10 is facing upward. Openings (not shown) may then be formed in the lower passivation layer 14 to expose a surface of the interposer lower bonding pads 14a. The openings may be formed, for example, by a photolithographic process, laser drilling or other suitable process. The C4 bumps 121 may then be formed in the openings in contact with the interposer lower bonding pads 14a. The C4 bumps 121 may be formed, for example, by an electroplating process or other suitable process.

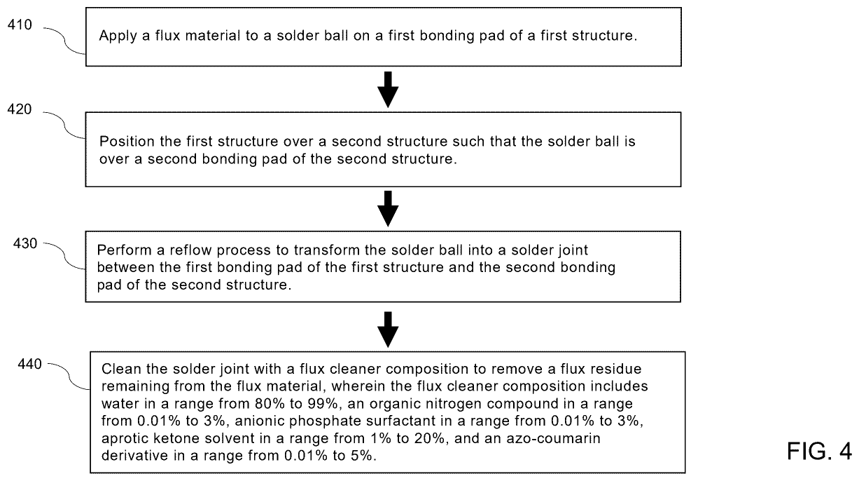

FIG. 4 is a flow chart illustrating an embodiment method of making a semiconductor structure (e.g., semiconductor module 120) according to one or more embodiments. Step 410 of the method may include applying a flux material to a solder ball on a first bonding pad of a first structure (e.g., semiconductor module 120). Step 420 may include positioning the first structure over a second structure (e.g., interposer 10) such that the solder ball is over a second bonding pad of the second structure. Step 430 may include performing a reflow process to transform the solder ball into a solder joint between the first bonding pad of the first structure and the second bonding pad of the second structure. Step 440 may include cleaning the solder joint with an embodiment flux cleaner composition to remove a flux residue remaining from the flux material, wherein the flux cleaner composition includes water in a range from 80% to 99%, an organic nitrogen compound in a range from 0.01% to 3%, anionic phosphate surfactant in a range from 0.01% to 3%, aprotic ketone solvent in a range from 1% to 20% and an azo-coumarin derivative in a range from 0.01% to 5%.

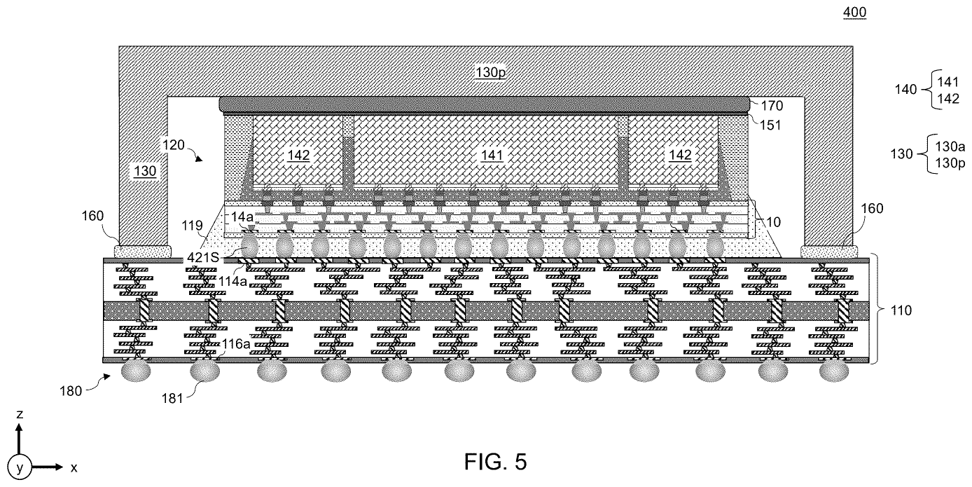

FIG. 5 is a vertical cross-sectional view of a package structure 400 including the semiconductor module 120 according to one or more embodiments. As illustrated in FIG. 5, the semiconductor module 120 may be mounted on a package substrate 110. The package substrate 110 may include a cored or coreless package substrate. The package substrate 110 may include upper bonding pads 114a on a chip-side surface of the package substrate 110. The package substrate 110 may also include lower bonding pads 116a on a board-side surface of the package substrate 110. The package substrate 110 may include a ball-grid array (BGA) 180 including a plurality of solder balls 181 contacting the lower bonding pads 116a on the board-side surface of the package substrate 110.

The semiconductor module 120 may be mounted on the package substrate 110 by a plurality of solder joints 421S on the board-side surface of the interposer 10. The solder joints 421S may be formed by reflow of the plurality of C4 bumps 121. The solder joints 421S may bond the interposer lower bonding pads 14a to the upper bonding pads 114a of the package substrate 110.

A package underfill 119 may be formed on the package substrate 110 and under and around the interposer 10. The package underfill layer 119 may also be formed around the solder joints 421S. The package underfill layer 119 may thereby securely fix the semiconductor module 120 to the package substrate 110. The package underfill layer 119 may be formed of an epoxy-based polymeric material.

A thermal interface material (TIM) layer 170 may be formed on the upper surface of the BSM layer 151. The TIM layer 170 may include, for example, a grease type TIM, a paste type TIM, film type TIM, a gel type TIM, graphite film TIM, a liquid metal TIM (e.g., a gallium-rich TIM), a PCM type TIM, etc. In at least one embodiment, the TIM layer 170 may include a low-melting-temperature (LMT) metal TIM. The PCM type TIM may include, for example, a polymer-based PCM TIM. The PCM type TIM may improve void and delamination issues, enhance thermal contact resistance and improve thermal performance in a package structure 400. In at least one embodiment, the PCM type TIM may change its phase from solid to high viscosity semi-liquid around 60° C. In at least one embodiment, the TIM layer 170 may include a gallium base, indium base, silver base, solder base, etc. Other types TIMs in the TIM layer 170 are within the contemplated scope of this disclosure.

The TIM layer 170 may be formed on the BSM layer 151 to dissipate heat generated during operation of the package structure 400 (e.g., operation of the semiconductor dies 140). The TIM layer 170 may be attached to the semiconductor module 120, for example, by a thermally conductive adhesive. The TIM layer 170 may have a low bulk thermal impedance and high thermal conductivity.

A package lid 130 may be located on the TIM layer 170 over the semiconductor module 120 and connected to the package substrate 110. The bond-line-thickness (BLT) (e.g., a distance between the package lid 130 and the semiconductor module 120) may be less than about 100 μm, although greater or lesser distances may be used. The package lid 130 may include a package lid plate portion 130p formed on the TIM layer 170 over the semiconductor module 120. The package lid 130 may also include a package lid foot portion 130a located around an outer periphery of the package lid plate portion 130p. The package lid foot portion 130a may be fixed to the package substrate 110 by an adhesive layer 160.

The package lid 130 may be formed, for example, of metal, ceramic or polymer material. In at least one embodiment, a material of the package lid 130 may include copper with a nickel coating surface. The nickel coating surface may have a thickness in a range of 1 μm to 10 μm. The package lid plate portion 130p may have a plate shape (e.g., planar shape) and be substantially parallel to an upper surface of the package substrate 110. The package lid plate portion 130p may extend, for example, in an x-y plane in FIG. 5. The package lid plate portion 130p may include an outer sidewall that is substantially aligned with an outer sidewall of the package lid foot portion 130a.

The adhesive layer 160 may be formed on the package substrate 110 near the sidewall of the semiconductor module 120. The adhesive layer 160 may bond the package lid foot portion 130a to package substrate 110. A thickness of the adhesive layer 160 may be in a range from 50 μm to 200 μm. The adhesive layer 160 may include, for example, a silicone adhesive (e.g., containing aluminum oxide, zinc oxide, resin, etc.) or an epoxy adhesive. Other suitable adhesives may be used. The adhesive layer 160 may contact the backside metal layer or the recessed upper surface of the upper molding material layer.

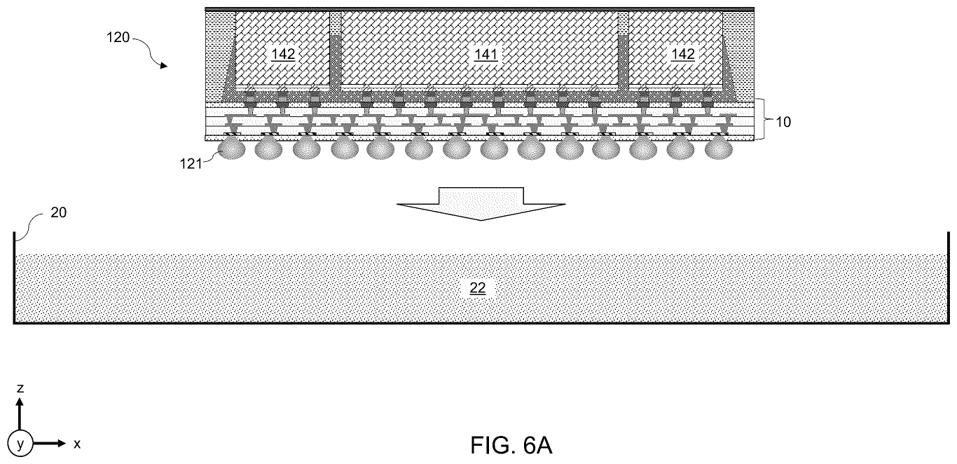

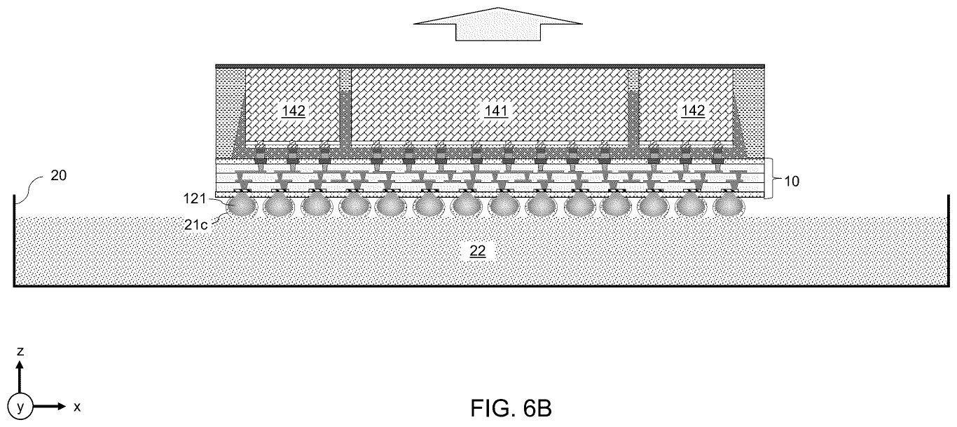

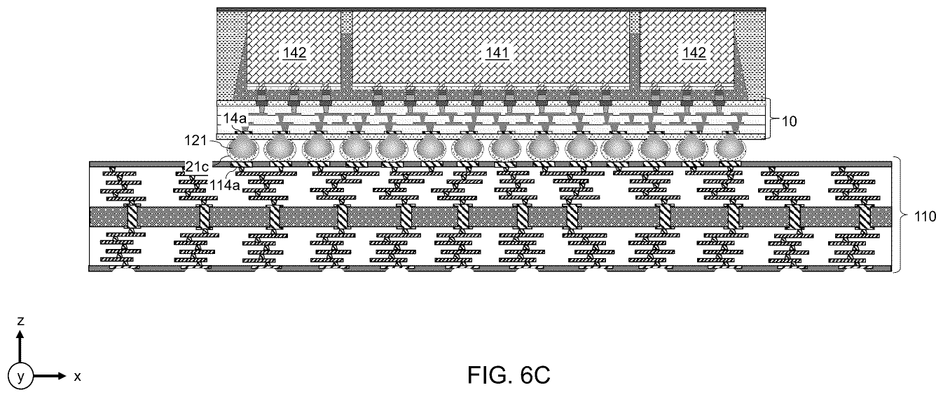

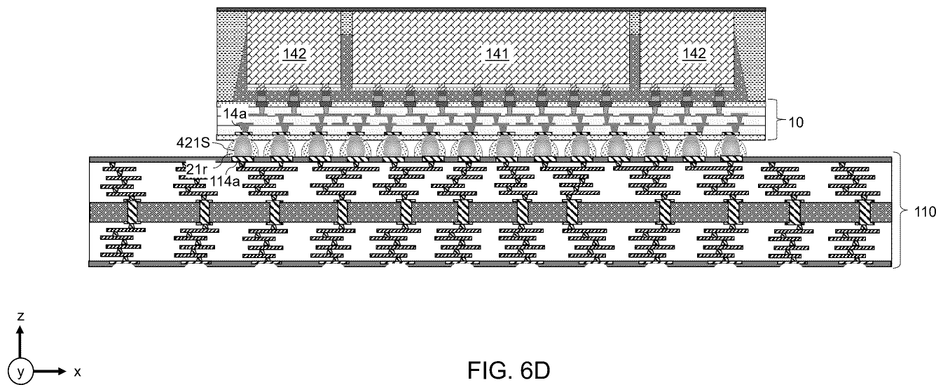

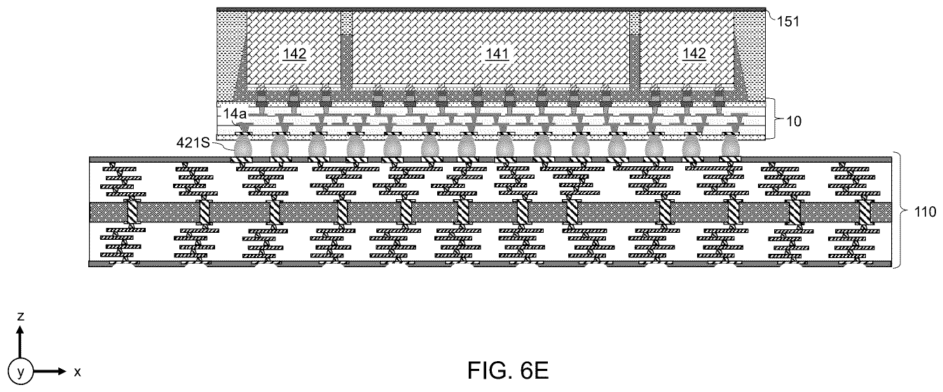

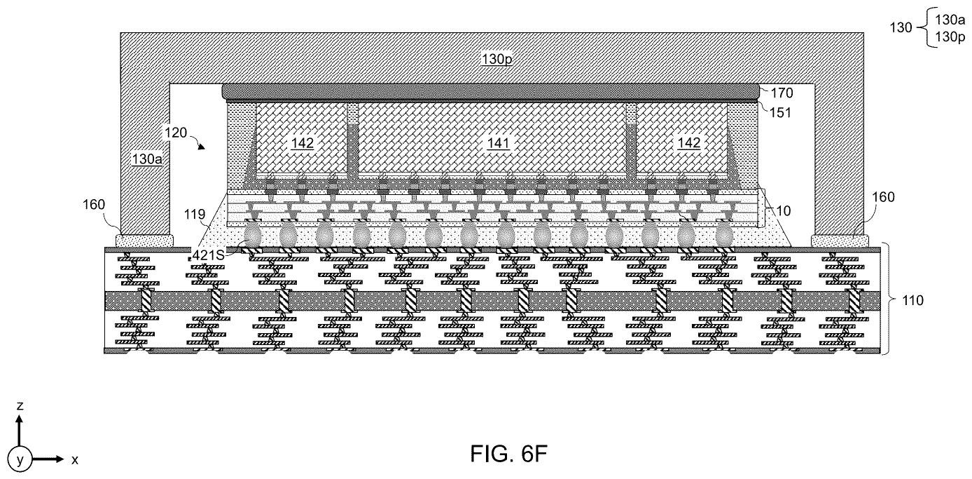

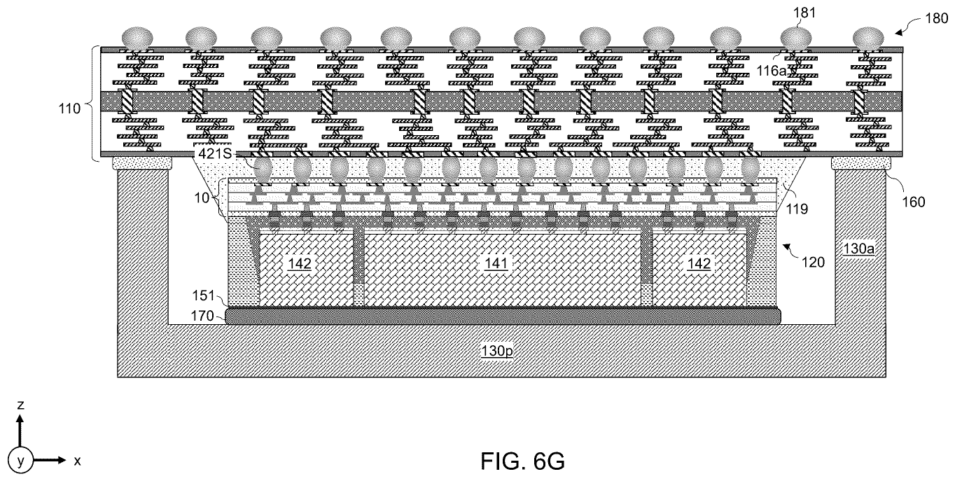

FIGS. 6A-6G illustrate various intermediate structures in a method of forming the package structure 400 according to one or more embodiments. FIG. 6A is a vertical cross-sectional view of an intermediate structure including the semiconductor module 120 according to one or more embodiments. Prior to mounting the semiconductor module 120 on the package substrate 110, the flux material 22 may be applied to the C4 bumps 121 on the semiconductor module 120. The C4 bumps 121 may be transformed into the solder joints 421S in a subsequent reflow process.

As illustrated in FIG. 6A, a process of applying the flux material 22 to the C4 bumps 121 may begin by positioning the semiconductor module 120 over the layer of flux material 22 in the container 20. The semiconductor module 120 may be positioned over the flux material 22 by the electromechanical pick-and-place (PNP) machine.

The flux material 22 may be applied to the C4 bumps 121 by a flux dipping process. A depth of the flux material 22 in the container 20 may be maintained at a level sufficient to allow the C4 bumps 121 to be immersed in the flux material 22. The PNP machine may lower the semiconductor module 120 into the flux material 22 so that the C4 bumps 121 are dipped in (e.g., immersed in) the flux material 22.

FIG. 6B is a vertical cross-sectional view of an intermediate structure including the semiconductor module 120 after application of the flux material 22 according to one or more embodiments. As illustrated in FIG. 6B, after the flux dipping process in which the C4 bumps 121 are dipped in the flux material 22, the electromechanical PNP machine may raise the C4 bumps 121 out of the flux material 22. A portion of the flux material 22 may adhere to the C4 bumps 121 and form a flux material coating 21c on a surface of the C4 bumps 121. In at least one embodiment, a thickness of the flux material coating 21c may be at least 5% of the diameter of the C4 bumps 121.

FIG. 6C is a vertical cross-sectional view of an intermediate structure including the semiconductor module 120 on the package substrate 110 according to one or more embodiments. The electromechanical PNP machine may position the semiconductor module 120 over the package substrate 110 such that the C4 bumps 121 coated with the flux material coating 21c are over the upper bonding pads 114a of the package substrate 110. The electromechanical PNP machine may then lower the semiconductor module 120 down onto the package substrate 110 such that the C4 bumps 121 coated with the flux material coating 21c are on the upper bonding pads 114a.

It should also be noted that the flux material 22 may be applied to the C4 bumps 121 by means other than dipping the C4 bumps 121 in the flux material 22. In at least one embodiment, the flux material 22 may be sprayed onto the C4 bumps 121 by a sprayer device (e.g., using selective flux jetting system). In at least one embodiment, the flux material 22 may be sprayed onto the C4 bumps 121 after the semiconductor module 120 has been placed on the package substrate 110. In at least one embodiment, the flux material 22 may also be sprayed onto the upper bonding pads 114a prior to placing the semiconductor module 120 on the package substrate 110. In that case, the upper bonding pads 114a may also include a flux material coating 21c similar to the flux material coating 21c on the C4 bumps 121.

FIG. 6D is a vertical cross-sectional view of an intermediate structure after a solder reflow process according to one or more embodiments. As illustrated in FIG. 6D, after the semiconductor module 120 is placed on the package substrate 110, a reflow process may be performed. The reflow process may transform the C4 bumps 121 into the solder joints 421S. The reflow process may be performed in a manner similar to the reflow process described above for the solder balls 28s. In particular, the intermediate structure may be placed in a reflow oven. A temperature of the reflow oven may be increased to a high temperature above the melting point of the solder material of the C4 bumps 121. The high temperature may cause the C4 bumps 121 to liquefy and flow so that a space between the interposer lower bonding pads 14a and the upper bonding pads 114a of the package substrate 110 may be substantially filled with solder material from the C4 bumps. The temperature of the reflow oven may then be gradually lowered to cause a controlled cooling of the reflowed solder material. The cooled solder material may solidify to form the solder joint 421S.

In at least one embodiment, the heating stages of the reflow process may be designed not only to melt the solder material but also to activate the flux material coating 21c. The activated flux material coating 21c may help remove oxides and impurities on the surfaces of the C4 bumps 121 and upper bonding pads 114a. As the flux material coating 21c is heated by the reflow process, its solvent components and some active ingredients may evaporate or decompose, producing gases that escape from the reflow oven.

However, not all of the flux material coating 21c may be consumed during the reflow process. After the reflow process, a portion of the flux material coating 21c may remain as flux residue 21r on and around the solder joint 421S. In particular, the flux residue 21r may remain on the upper bonding pad 114a. In at least one embodiment, the flux residue 21r may include polymeric flux residue.

FIG. 6E is a vertical cross-sectional view of an intermediate structure after performing a flux cleaning process according to one or more embodiments. The remaining flux residue 21r, in instances in which the flux residue 21r may be left on the intermediate structure, can lead to issues such as corrosion, poor electrical performance, or even physical damage over time. Therefore, after the reflow process is used to form the solder joint 421S, a flux cleaning process may be performed to remove any flux residue 21r on or around the solder joint 421S and the upper bonding pad 114a.

The flux cleaning process may include a pre-rinse step in which the intermediate structure (e.g., the solder joint 421S and upper bonding pad 114a) may be immersed in or sprayed with deionized water or a mild cleaning solution to begin breaking down the flux residue 21r before the main cleaning cycle. This step may help soften and remove a loosely adhered portion of the flux residue 21r.

A cleaning step may then be performed using an embodiment flux cleaner composition according to one more embodiments (e.g., prepared by a method illustrated by the flowchart in FIG. 1). In the cleaning step, the intermediate structure may be immersed in the embodiment flux cleaner composition. In at least one embodiment, an entirety of the intermediate structure (e.g., a semiconductor wafer including the intermediate structure) may be immersed in the embodiment flux cleaner composition. In at least one embodiment, at least the solder joint 421S and upper bonding pad 114a of the intermediate structure may be immersed in the embodiment flux cleaner composition. The intermediate structure may alternatively or additionally be sprayed with the embodiment flux cleaner composition using a sprayer device. In at least one embodiment, at least the solder joint 421S and upper bonding pad 114a of the intermediate structure may be sprayed with the embodiment flux cleaner composition. The embodiment flux cleaner composition may dissolve the flux residue 21r remaining on and around the solder joint 421S and upper bonding pad 114a.

In at least one embodiment, the embodiment flux cleaner composition may include the organic nitrogen compound (e.g., alkaline organic amine) and azo-coumarin derivative (e.g., azo-coumarin inhibitor). In particular, the organic nitrogen compound and azo-coumarin derivative may protect the exposed metal surfaces in the intermediate structure from damage (e.g., etching, corrosion, etc.) by the embodiment flux cleaner composition. In particular, the organic nitrogen compound and azo-coumarin derivative may protect the BSM layer 151 from damage. Unlike a related flux cleaner compositions, the flux cleaner composition according to one or more embodiments may not etch a metal layer on a backside of a stacked semiconductor package (e.g., a chip-on-wafer-on-substrate package). This makes the embodiment flux cleaner composition suitable for cleaning semiconductor packages with a BSM layer 151, unlike the related flux cleaner composition.

In at least one embodiment, the cleaning step may include agitation to enhance the cleaning action of the flux cleaner composition. The agitation may include, for example, ultrasonic agitation, rotational agitation, and high-pressure spray jets or nozzles that direct the flux cleaner composition at the intermediate structure (e.g., on and around the solder joint 421S and upper bonding pad 114a) from one or more angles.

After the cleaning step, the intermediate structure (e.g., on and around the solder joint 421S and upper bonding pad 114a) may be rinsed with water (e.g., deionized water) to removes any remaining cleaning solution, along with any flux residue 21r. The intermediate structure may then be dried using a hot air blower (e.g., directing heated air onto the intermediate structure), vacuum drying (e.g., using reduced pressure to evaporate residual moisture quickly, or infrared heating. The intermediate structure may then be inspected using optical or X-ray inspection to verify that all of the flux residue 21r has been removed and to ensure that the solder joint 421S is high-quality and reliable.

FIG. 6F is a vertical cross-sectional view of an intermediate structure including the package lid 130 according to one or more embodiments. As illustrated in FIG. 6F, after the semiconductor module 120 is mounted on the package substrate 110, the package underfill layer 119 may be deposited (e.g., injected) on the package substrate 110 and under the semiconductor module 120 by a suitable method. The package underfill layer 119 may be formed around the solder joints 421S. The TIM layer 170 may then be placed on the BSM layer 151. The adhesive layer 160 may then be formed on the package substrate 110 and the package lid 130 placed over the semiconductor module 120 so that the package lid foot portion 130a aligns with the adhesive layer 160. The package lid 130 may then be clamped together with the package substrate 110 by a heat clamp until the adhesive layer 160 is cured.

FIG. 6G illustrates a vertical cross-sectional view of an intermediate structure in which the BGA 180 including the plurality of solder balls 181 may be formed on the package substrate 110 according to one or more embodiments. The plurality of solder balls 181 may be formed on the lower bonding pads 116a through openings in a lower passivation layer of the package substrate 110. The solder balls 181 may be formed, for example, by an electroplating process.

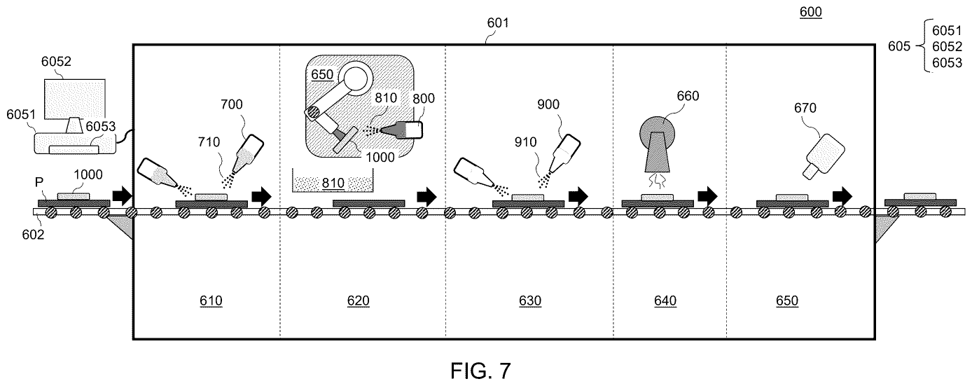

FIG. 7 is a schematic illustration of an automated flux cleaning system 600 according to one or more embodiments. As illustrated in FIG. 7, the flux cleaning system 600 may include a housing unit 601 for housing various sections of the flux cleaning system 600. The flux cleaning system 600 may include a conveyor device 602 for transporting a carrier plate P supporting a semiconductor device 1000 (e.g., a wafer including a semiconductor module 120, semiconductor structure 400, etc.) through the flux cleaning system 600. The conveyor device 602 may include, for example, an electric conveyor device including a conveyor belt driven by one or more rollers.

The flux cleaning system 600 may also include a control device 605 for controlling an operation of the flux cleaning system 600. The control device 605 may include, for example, a computer 6051 (e.g., server) executing instructions for performing a flux cleaning method in the flux cleaning system 600. The computer 6051 may include a memory (e.g., read-only memory (ROM), random access memory (RAM), etc.) for storing the instructions and data, and a processing device (e.g., central processing unit (CPU) for executing the instructions and processing the data. The control device 605 may also include a monitor 6052 that displays data generated by the computer 6051 and pertaining to an operation or status of the flux cleaning system 600. The control device 605 may also include an input device 6053 (e.g., keyboard, mouse, touchpad) that may be used by a human operator to input data and instructions into the computer 6051 to coordinate operation of the flux cleaning system 600.

As further illustrated in FIG. 7, the flux cleaning system 600 may include a pre-cleaning section 610, a cleaning section 620 (e.g., immersion chamber), a rinsing section 630 (e.g., spraying chamber), a drying section 640 (e.g., drying chamber) and an inspection section 670 (e.g., inspection chamber). The conveyor device 602 may transport the carrier plate P supporting the semiconductor device 1000 into the housing unit 601 and the pre-cleaning section 610. The pre-rinse section 610 may include a high-pressure sprayer 700 that sprays pre-cleaning solution 710 (e.g., a mild cleaning solution) onto the semiconductor device 1000. In particular, the high-pressure sprayers 700 may spray the pre-cleaning solution 710 on and around the solder joints (e.g., solder joints 128S, solder joints 421S, etc.) in the semiconductor device 1000. The pre-cleaning solution 710 may include, for example, de-ionized water, a solvent such as isopropyl alcohol, surfactant, etc.

The conveyor device 602 may then transport the carrier plate P supporting the semiconductor device 1000 into the cleaning section 620. The cleaning section 620 may include one or more high-pressure sprayers 800 that sprays the flux cleaner composition 810 according to one more embodiments (e.g., prepared by a method illustrated by the flowchart in FIG. 1), onto the semiconductor device 1000. In particular, the high-pressure sprayers 800 may spray the flux cleaner composition 810 on and around the solder joints (e.g., solder joints 128S, solder joints 421S, etc.) in the semiconductor device 1000. The high-pressure sprayers 800 may spray the flux cleaner composition 810 onto the semiconductor device 1000 from a plurality of different angles and at a plurality of different pressures.

The cleaning section 620 may also include an electromechanical PNP machine 650 for lifting the semiconductor device 1000 and immersing the semiconductor device 1000 in an embodiment flux cleaner composition 810. The cleaning section 620 may also include an agitation mechanism that may be used to enhance the cleaning action of the embodiment flux cleaner composition 810. The agitation mechanism may utilize, for example, ultrasonic agitation, rotational agitation, etc. The agitation mechanism may be implemented at least in part by the electromechanical PNP machine 650. The embodiment flux cleaner composition 810 may dissolve the flux residue (e.g., flux residue 22r, flux residue 21r, etc.) remaining on and around the solder joints (e.g., solder joints 128S, solder joints 421S, etc.) in the semiconductor device 1000.

The conveyor device 602 may then transport the carrier plate P supporting the semiconductor device 1000 into the rinsing section 630. The rinsing section 630 may include one or more high-pressure sprayers 900 that sprays a rinsing solution 910 onto the semiconductor device 1000. The high-pressure sprayers 800 may spray the flux cleaner composition 810 onto the semiconductor device 1000 from a plurality of different angles and at a plurality of different pressures. In particular, the high-pressure sprayers 900 may spray the rinsing solution 910 on and around the solder joints (e.g., solder joints 128S, solder joints 421S, etc.) in the semiconductor device 1000. The rinsing solution 910 may include, for example, de-ionized water, a solvent such as isopropyl alcohol, etc. The rinsing solution 910 may help to wash away the remaining flux cleaner composition and any flux residue (e.g., flux residue 22r, flux residue 21r, etc.) remaining on and around the solder joints (e.g., solder joints 128S, solder joints 421S, etc.) in the semiconductor device 1000.

The conveyor device 602 may then transport the carrier plate P supporting the semiconductor device 1000 into the drying section 640. The drying section 640 may include an electric dryer 660 that may heat the semiconductor device 1000 to remove the rinsing solution 910 remaining on the semiconductor device 1000. The electric dryer 660 may include, for example, a hot air blower directing heated air onto the semiconductor device 1000, a vacuum dryer using reduced pressure to evaporate the rinsing solution 910, infrared heater, etc.

The conveyor device 602 may then transport the carrier plate P supporting the semiconductor device 1000 into the inspection section 650. The inspection section 670 may include an inspection device 670 that may capture an image of the semiconductor device 1000 to be displayed on the monitor 6052. The image displayed on the monitor 6052 may be evaluated by an operator to verify that all of the flux residue (e.g., flux residue 22r, flux residue 21r, etc.) has been removed and to ensure that the solder joint (e.g., solder joint 128S, solder joint 421S, etc.) is high-quality and reliable. The control device 605 may alternatively include an image analyzing function allowing the control device 605 to analyze the image to detect any remaining flux residue and/or any defect in the solder joints in the semiconductor device 1000, and display a result of the image analysis on the monitor 6052. The inspection device 670 may include, for example, an optical inspection device, X-ray inspection device, etc.). The inspection device 670 may be configured to inspect the dried semiconductor device 1000 (e.g., the dried wafer including a semiconductor module 120, semiconductor structure 400, etc.) to ensure that the dried wafer is substantially free of flux residue (e.g., flux residue 22r, flux residue 21r, etc.). The conveyor device 602 may then transport the carrier plate P supporting the semiconductor device 1000 out of the inspection section 650 and the housing unit 601.

Referring to FIGS. 1 to 7, an embodiment flux cleaner composition 810 may include water in a range from 80% to 99%, an organic nitrogen compound in a range from 0.01% to 3%, anionic phosphate surfactant in a range from 0.01% to 3%, aprotic ketone solvent in a range from 1% to 20%, and an azo-coumarin derivative in a range from 0.01% to 5%.

In an embodiment, the anionic phosphate surfactant may include at least one of lauryl phosphate, sodium octyl phosphate or octylphenyl ether phosphate. In an embodiment, the anionic phosphate surfactant may include a compound represented by a chemical formula:

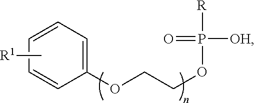

where the R1 group may be an alkyl group, an alkenyl group, a phenyl group or substituted phenyl group, an alkoxy group, or a cyclic alkyl group, the R group may be a hydroxyl group and n may be an integer in a range from 1 to 50. In at least one embodiment, the R1 group may be C₈H₁₇, the R group may be OH and n=10. In an embodiment, the aprotic ketone solvent may include 1,3-dimethyl-2-imidazolidinone. The organic nitrogen compound may include an alkaline organic amine. In an embodiment, the organic nitrogen compound may include at least one of ethanolamine, tetramethyl ammonium hydroxide, aminopropanol, 2-(methylamino) ethanol, or 2-(2-aminoethylamino) ethanol. In an embodiment, the organic nitrogen compound may include ethanolamine. In an embodiment, the azo-coumarin derivative may include a compound represented by a chemical formula:

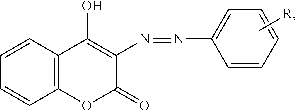

where R may be one of a hydrogen atom, a bromine atom, a chlorine atom, a methyl group, an ethoxy group, a nitrile group or a nitro group. In at least one embodiment the R group may be a hydrogen atom. In at least one embodiment, an amount of the water may be about 95%, an amount of the organic nitrogen compound may be about 1%, an amount of the anionic phosphate surfactant may be about 0.1%, an amount of the aprotic ketone solvent may be about 3.8%, and an amount of the azo-coumarin derivative may be about 0.1%.

Referring again to FIGS. 1 to 7, a method of making a semiconductor structure 120, 400 may include applying a flux material 22 to a solder ball 28s, 121 on a first bonding pad 145, 14a of a first structure 140, 120, positioning the first structure 140, 120 over a second structure 10, 110 such that the solder ball 28s, 121 may be over a second bonding pad 13a, 114a of the second structure 10, 110, performing a reflow process to transform the solder ball 28s, 121 into a solder joint 128S, 421S between the first bonding pad 145, 14a of the first structure 140, 120 and the second bonding pad 13a, 114a of the second structure 10, 110, and cleaning the solder joint 128S, 421S with a flux cleaner composition 810 to remove a flux residue remaining from the flux material 22, wherein the flux cleaner composition 810 may include water in a range from 80% to 99%, an organic nitrogen compound in a range from 0.01% to 3%, anionic phosphate surfactant in a range from 0.01% to 3%, aprotic ketone solvent in a range from 1% to 20%, and an azo-coumarin derivative in a range from 0.01% to 5%.

In an embodiment, the applying of the flux material 22 may include dipping the solder ball 28s, 121 in the flux material 22. In an embodiment, the cleaning of the solder joint 128S, 421S may include spraying the flux cleaner composition 810 on the solder joint 128S, 421S. In an embodiment, the semiconductor structure 120, 400 may be on a semiconductor wafer and the cleaning of the solder joint 128S, 421S may include immersing the semiconductor wafer in the flux cleaner composition 810. In an embodiment, the first structure 140 may include a semiconductor die 140 including a plurality of solder balls 28s, the second structure 10 may include an interposer 10 and the performing of the reflow process may include transforming the plurality of solder balls 28s into a plurality of solder joint 128S between the semiconductor die 140 and the interposer 10. In an embodiment, the method may further include before the cleaning of the solder joint 128S, forming a backside metal layer 151 on a backside of the semiconductor die 140, wherein the cleaning of the solder joint 128S may include cleaning the solder joint 128S without damaging the backside metal layer 151. In an embodiment, the first structure 120 may include a semiconductor module 120 including a plurality of C4 bumps 121, the second structure 110 may include a package substrate 110 and the performing of the reflow process may include transforming the plurality of C4 bumps 121 into a plurality of solder joints 421S between the semiconductor module 120 and the package substrate 110. In at least one embodiment, the amount of the water may be about 95%, the amount of the organic nitrogen compound may be about 1%, the amount of the anionic phosphate surfactant may be about 0.1%, the amount of the aprotic ketone solvent may be about 3.8%, and the amount of the azo-coumarin derivative may be about 0.1%.

Referring again to FIGS. 1 to 7, a flux residue cleaning system 600 may include an immersion chamber 620 including a container containing a first solution 810 and configured to receive a wafer 1000 including a semiconductor structure 120, 400 such that the semiconductor structure 120, 400 may be immersed in the first solution, wherein the first solution 810 may include a flux cleaner composition 810 including water in a range from 80% to 99%, an organic nitrogen compound in a range from 0.01% to 3%, anionic phosphate surfactant in a range from 0.01% to 3%, aprotic ketone solvent in a range from 1% to 20%, and an azo-coumarin derivative in a range from 0.01% to 5%, a spraying chamber 630 configured to receive the wafer 1000 from the immersion chamber, and including a sprayer 900 configured to spray a second solution 910 onto the semiconductor structure 120, 400, and a drying chamber 640 configured to dry the wafer 1000 received from the spraying chamber 630.

In an embodiment, the flux residue cleaning system 600 may further include an inspection chamber 650 configured to inspect the dried wafer 1000 to ensure that the dried wafer 1000 may be substantially free of flux residue 22r, 21r.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A flux cleaner composition, comprising:
water in a range from 80% to 99%;
an organic nitrogen compound in a range from 0.01% to 3%;
anionic phosphate surfactant in a range from 0.01% to 3%;
aprotic ketone solvent in a range from 1% to 20%; and
an azo-coumarin derivative in a range from 0.01% to 5%.

2. The flux cleaner composition of claim 1, wherein the anionic phosphate surfactant comprises at least one of lauryl phosphate, sodium octyl phosphate or octylphenyl ether phosphate.

3. The flux cleaner composition of claim 1, wherein the anionic phosphate surfactant comprises a compound represented by a chemical formula: 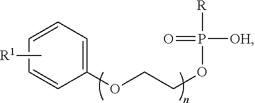
where the R¹ group is an alkyl group, an alkenyl group, a phenyl group or substituted phenyl group, an alkoxy group, or a cyclic alkyl group, the R group is a hydroxyl group and n is an integer in a range from 1 to 50.

4. The flux cleaner composition of claim 1, wherein the aprotic ketone solvent comprises 1,3-dimethyl-2-imidazolidinone.

5. The flux cleaner composition of claim 1, wherein the organic nitrogen compound comprises an alkaline organic amine.

6. The flux cleaner composition of claim 1, wherein the organic nitrogen compound comprises at least one of ethanolamine, tetramethyl ammonium hydroxide, aminopropanol, 2-(methylamino) ethanol, or 2-(2-aminoethylamino) ethanol.

7. The flux cleaner composition of claim 1, wherein the organic nitrogen compound comprises ethanolamine.

8. The flux cleaner composition of claim 1, wherein the azo-coumarin derivative comprises a compound represented by a chemical formula: 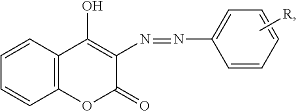
where R is one of a hydrogen atom, a bromine atom, a chlorine atom, a methyl group, an ethoxy group, a nitrile group or a nitro group.

9. The flux cleaner composition of claim 8, wherein the R group is a hydrogen atom.

10. The flux cleaner composition of claim 1, wherein an amount of the water is about 95%, an amount of the organic nitrogen compound is about 1%, an amount of the anionic phosphate surfactant is about 0.1%, an amount of the aprotic ketone solvent is about 3.8%, and an amount of the azo-coumarin derivative is about 0.1%.

11. A method of making a semiconductor structure, the method comprising:
applying a flux material to a solder ball on a first bonding pad of a first structure;
positioning the first structure over a second structure such that the solder ball is over a second bonding pad of the second structure;
performing a reflow process to transform the solder ball into a solder joint between the first bonding pad of the first structure and the second bonding pad of the second structure; and
cleaning the solder joint with a flux cleaner composition to remove a flux residue remaining from the flux material, wherein the flux cleaner composition comprises:
water in a range from 80% to 99%;
an organic nitrogen compound in a range from 0.01% to 3%;
anionic phosphate surfactant in a range from 0.01% to 3%;
aprotic ketone solvent in a range from 1% to 20%; and
an azo-coumarin derivative in a range from 0.01% to 5%.

12. The method of claim 11, wherein the applying of the flux material comprises dipping the solder ball in the flux material.

13. The method of claim 11, wherein the cleaning of the solder joint comprises spraying the flux cleaner composition on the solder joint.

14. The method of claim 11, wherein the semiconductor structure is on a semiconductor wafer and the cleaning of the solder joint comprises immersing the semiconductor wafer in the flux cleaner composition.

15. The method of claim 11, wherein the first structure comprises a semiconductor die including a plurality of microbumps, the second structure comprises an interposer and the performing of the reflow process comprises transforming the plurality of microbumps into a plurality of solder joints between the semiconductor die and the interposer.

16. The method of claim 15, further comprising:
before the cleaning of the solder joint, forming a backside metal layer on a backside of the semiconductor die, wherein the cleaning of the solder joint comprises cleaning the solder joint without damaging the backside metal layer.

17. The method of claim 11, wherein the first structure comprises a semiconductor module including a plurality of C4 bumps, the second structure comprises a package substrate and the performing of the reflow process comprises transforming the plurality of C4 bumps into a plurality of solder joints between the semiconductor module and the package substrate.

18. The method of claim 11, wherein an amount of the water is about 95%, an amount of the organic nitrogen compound is about 1%, an amount of the anionic phosphate surfactant is about 0.1%, an amount of the aprotic ketone solvent is about 3.8%, and an amount of the azo-coumarin derivative is about 0.1%.

19. A flux residue cleaning system, comprising:
an immersion chamber including a container containing a first solution and configured to receive a wafer including a semiconductor structure such that the semiconductor structure is immersed in the first solution, wherein the first solution comprises a flux cleaner composition comprising:
water in a range from 80% to 99%;
an organic nitrogen compound in a range from 0.01% to 3%;
anionic phosphate surfactant in a range from 0.01% to 3%;
aprotic ketone solvent in a range from 1% to 20%; and
an azo-coumarin derivative in a range from 0.01% to 5%;
a spraying chamber configured to receive the wafer from the immersion chamber, and including a sprayer configured to spray a second solution onto the semiconductor structure; and
a drying chamber configured to dry the wafer received from the spraying chamber.

20. The flux residue cleaning system of claim 19, further comprising:
an inspection chamber configured to inspect the dried wafer to ensure that the dried wafer is substantially free of flux residue.
